(19) United States
(12) Patent Application Publication
(10) Pub. No.: US 2005/0088175 A1
(43) Pub. Date: Apr. 28, 2005

(54) Permalloy magnetization reversal sensor

(75) Inventors: Jason M. Chilcote, Frisco, TX (US); Perry A. Holman, Richardson, TX (US)

Correspondence Address: Kris T. Fredrick;Honeywell International, Inc., 101 Columbia Rd., P.O. Box 2245, Morristown, NJ, 07962, US

(73) Assignee: Honeywell International Inc.

(21) Appl. No.: 10/692,883

(22) Filed: Oct. 25, 2003

(51) Int. Cl. G01R 33/09; G01B 7/30

(52) U.S. Cl. 324/252; 324/253; 324/207.21

(57) ABSTRACT

A magnetic sensor is disclosed in which a ferromagnetic runner (e.g., a permalloy runner) can be located relative to a target. A coil structure is generally wound about the ferromagnetic runner, such that when a magnetic field changes direction along an axial length of the ferromagnetic runner, a voltage is induced in the coil structure that is proportional to a time range of change of a magnetic flux density, due to the sudden internal magnetization reversal of the runner. Additionally, an interfacing circuit can be provided in which the ferromagnetic runner and the coil structure are integrated with the interfacing circuit to thereby produce a magnetic sensor for magnetically sensing the target. The magnetic sensor is highly sensitive and can operate without electrical current or upon a negligible electrical current.

### TECHNICAL FIELD

Embodiments are generally related to magnetic sensors. Embodiments are also related to magnetoresistive materials and magnetoresistive-based sensors. Embodiments are additionally related to permalloy materials and magnetic sensors which incorporate such permalloy materials.

### BACKGROUND OF THE INVENTION

Magnetoresistors are often utilized for the contactless detection of changes in state, such as the measurement of an angular position of a rotatably mounted part. Magnetoresistive-based sensors typically include magnetic field-dependent resistors, which are arranged in a bridge circuit configuration and through which a control current is fed. When a magnetoresistive-based sensor is influenced by a magnetic field, a voltage can be established in which the magnitude of the voltage depends on the magnitude and direction of the magnetic field associated with the sensor.

The relationship between an associated bridge circuit voltage and the magnetic field direction can be utilized in a contactless magnetoresistive sensor, for example, to detect the angular position of a rotatably mounted part. Such sensors are particularly useful in automotive applications. Magnetoresistive sensors are typically configured from a magnetoresistive film that is formed from a magnetic substance that exhibits a magnetoresistive effect and generally possesses a single active layered structure.

A magnetoresistive sensor may be acted upon by a magnetic field oriented in a particular manner, such that a definite control current can be applied to the current contacts of an associated bridge circuit. The voltage that is then established at the other contacts can be measured on an ongoing basis. In general, the serpentine pattern of magnetoresistive material utilized in magnetoresistive sensors can be connected electrically in a Wheatstone bridge arrangement in order to sense changes in the resistance of the magnetoresistive material in response to changes in the strength and direction of a magnetic field component in the plane of the magnetoresistive elements. In order to monitor the changes in the resistance of the material, associated components, such as amplifiers, are generally connected together to form an electrical circuit, which provides an output signal that is representative of the strength and direction of the magnetic field in the plane of the sensing elements.

When the circuit is provided on a silicon substrate, for example, electrical connections between associated components can be made above the surface of the silicon or by appropriately doped regions beneath the components and within the body of the silicon substrate. Components can be connected to each other above the surface of the silicon by disposing conductive material to form electrically conductive paths between the components. When appropriately doped regions within the silicon substrate connect components in electrical communication with each other, an electrically conductive path can be formed by diffusing a region of the silicon with an appropriate impurity, such as phosphorous, arsenic or boron to form electrically conductive connections between the components.

Sensors may utilize an integrated coil that senses the magnetization flip of a single un-powered permalloy runner. Note that as utilized herein, the term “permalloy” generally refers to any of several alloys of nickel and iron having high magnetic permeability. Typical magnetoresistive devices utilize the small electrical resistance change of the permalloy film to a magnetic field by forcing a current through the runner and measuring the voltage change. This is often accomplished in a Wheatstone bridge configuration with many runners arranged electrically in series per bridge element to maintain the current low and the sensitivity high.

Based on the foregoing, it would therefore be advantageous to produce a magnetic sensor that exhibits a high sensitivity, low current, and which is small and inexpensive. It would also be advantageous to produce a magnetic sensor which does not rely on many runners per bridge element, but utilizes a minimum number of permalloy runners, and in particular, which do not require an electrical current for operations thereof. It is believed that if such a configuration can be effectively produced; magnetic sensors can be implemented which are much more compact and efficient than present magnetic sensors.

### BRIEF SUMMARY OF THE INVENTION

The following summary of the invention is provided to facilitate an understanding of some of the innovative features unique to the present invention and is not intended to be a full description. A full appreciation of the various aspects of the invention can be gained by taking the entire specification, claims, drawings, and abstract as a whole.

It is, therefore, one aspect of the present invention to provide an improved magnetic sensor.

It is another aspect of the present invention to provide for an improved magnetoresistive sensor.

It is yet a further aspect of the present invention to provide for a permalloy magnetic sensor.

It is an additional aspect of the present invention to provide for a permalloy magnetic sensor, which utilizes at a minimum, only one permalloy runner and does not require a current for operations thereof. The aforementioned aspects of the invention and other objectives and advantages can now be achieved as described herein. A magnetic sensor is disclosed in which a ferromagnetic runner (e.g., a permalloy runner) can be located relative to a target. A coil structure can be generally wound about the ferromagnetic runner, such that when a magnetic field changes direction along an axial length of the ferromagnetic runner (e.g., above a certain level, H_{c}), a voltage is induced in the coil structure that is proportional to a time range of change of a magnetic flux thereof.

Additionally, an interfacing circuit can be provided, wherein the ferromagnetic runner and the coil structure are integrated with the interfacing circuit to thereby produce a magnetic sensor for magnetically sensing the target, wherein the magnetic sensor is highly sensitive and operates upon a negligible electrical current. The coil structure itself can be wound tightly about the ferromagnetic runner, such that the coil structure possesses a number of turns thereof, which is sufficient to achieve a voltage spike amplitude for the interfacing circuit induced therein when the magnetic field causes the internal magnetization to change direction along the axial length of the ferromagnetic runner.

The ferromagnetic runner and the coil can also be integrated with the interfacing circuit utilizing either levels of interconnecting metal or a conductive semiconductor layer for the coil structure, such that the conductive semiconductor layer is located between the ferromagnetic runner and an insulating above. The voltage induced in the coil structure is equivalent to a number of turns of the coil structure multiplied by a cross sectional area of the ferromagnetic runner multiplied by a rate of change of magnetic flux density with respect to a change of time. Additionally, a single device can provide speed and direction information.

### BRIEF DESCRIPTION OF THE DRAWINGS

The accompanying figures, in which like reference numerals refer to identical or functionally-similar elements throughout the separate views and which are incorporated in and form a part of the specification, further illustrate the present invention and, together with the detailed description of the invention, serve to explain the principles of the present invention.

FIG. 1 illustrates a permalloy runner having a magnetization direction along an axial length, in accordance with a preferred embodiment of the present invention;

FIG. 2 illustrates the permalloy runner of FIG. 1 having a reverse magnetization direction along the axial length thereof, in accordance with a preferred embodiment of the present invention;

FIG. 3 illustrates the permalloy runner of FIGS. 1-2 having a wound coil thereof, in accordance with a preferred embodiment of the present invention;

FIG. 4 illustrates a graph of output voltage versus applied field for the permalloy runner depicted in FIGS. 1-3 herein, in accordance with a preferred embodiment of the present invention; and

FIG. 5 illustrates a block diagram of a configuration in which an interfacing circuit is adapted for use with a ferromagnetic runner and a coil structure, in accordance with an alternative embodiment of the present invention.

### DETAILED DESCRIPTION OF THE INVENTION

The particular values and configurations discussed in these non-limiting examples can be varied and are cited merely to illustrate at least one embodiment of the present invention and are not intended to limit the scope of the invention.

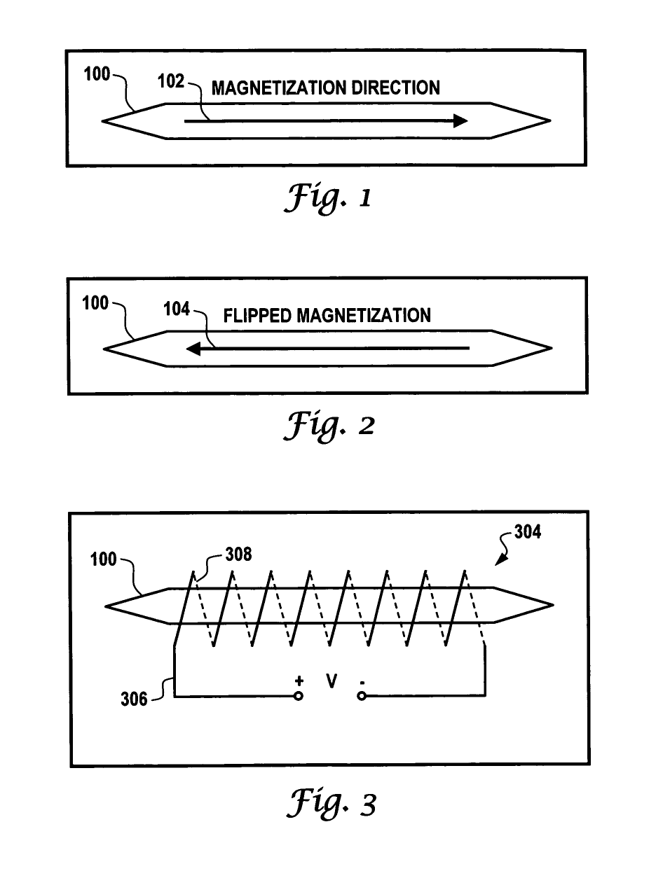

FIG. 1 illustrates a permalloy runner 100 having a magnetization direction along an axial length, in accordance with a preferred embodiment of the present invention. FIG. 2 illustrates the permalloy runner 100 of FIG. 1 having a reverse magnetization direction along the axial length thereof, in accordance with a preferred embodiment of the present invention. FIG. 3 illustrates the permalloy runner 100 of FIGS. 1-2 having a wound coil thereof, in accordance with a preferred embodiment of the present invention. Note that in FIGS. 1-3, like or analogous parts are generally indicated by identical reference numerals.

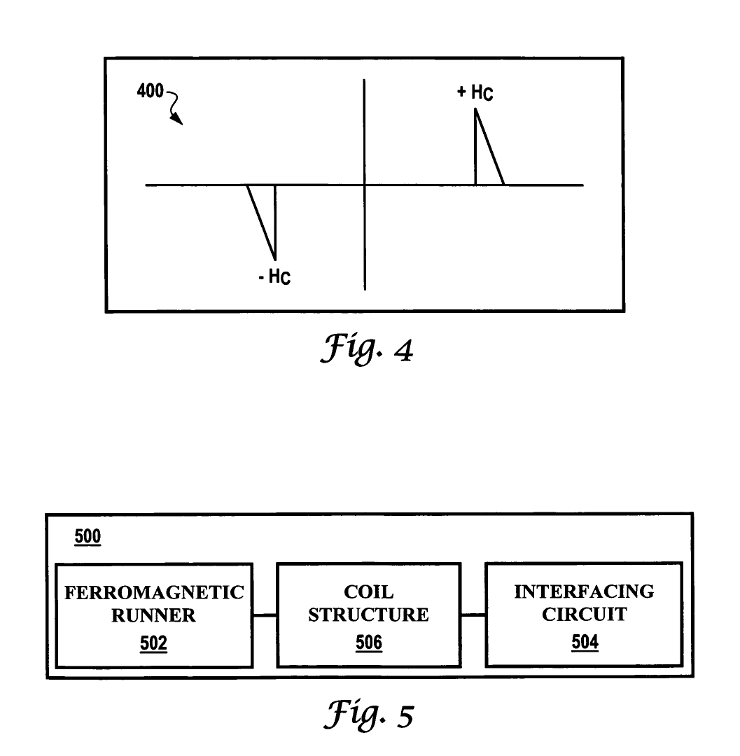

As indicated in FIG. 3, a single coil 304 can be wound about the permalloy runner 100, such that when a magnetic field changes direction along an axial length of the permalloy runner, as indicated by arrow 102 of FIG. 1 and arrow 104 of FIG. 4, a voltage, V, is induced in the coil that 304 is proportional to a time rate of change of a magnetic flux thereof. Voltage V is shown in FIG. 3. An interfacing circuit can be implemented in which the permalloy runner 100 and the coil 304 are integrated to thereby produce a magnetic sensor for magnetically sensing a target, wherein the magnetic sensor is highly sensitive and operates upon a negligible electrical current.

Additionally, a plurality of interconnecting metals 306 and 308 can be utilized to integrate the permalloy runner 100 and the coil 304 with the interfacing circuit. When a magnetic field changes direction in the axis of the permalloy runner 100 length, the sudden magnetization reversal (i.e., see arrows 102 and 104) induces a voltage in the surrounding coil 304 that is proportional to the time rate of change of the magnetic flux linking the interfacing circuit. Coil 304 can be tightly wound about the permalloy runner 100 with a sufficient number of turns to obtain the required voltage spike amplitude for the interfacing circuit.

The permalloy runner 100 and the coil 304 can be integrated with the interfacing circuit using either multiple levels of interconnecting metal such as interconnecting metal 306 and 308, or utilizing a conductive semiconductor layer such as a sinker resistor for coil structure beneath the permalloy runner 100 and insulated metal located above the permalloy runner. Interconnecting metal 306 of FIG. 3 refers generally to coil interconnecting metal located above permalloy runner 100, while interconnecting metal 308 refers to interconnecting metal (or semiconductor layers) located below permalloy runner 100. The configuration illustrated with respect to FIGS. 1-3 generally utilizes only one coil structure and only one ferromagnetic cell (i.e., permalloy runner 100) component based on the shape anisotropy of the ferromagnetic cell.

FIG. 4 illustrates a graph 400 of output voltage versus applied field for the permalloy runner depicted in FIGS. 1-3 herein, in accordance with a preferred embodiment of the present invention. Graph 400 can be produced based on equation (1) below, which is based on determining voltage V depicted in FIG. 3. The voltage V induced in the single coil 304 is generally equivalent to the number of turns of the coil multiplied by a cross sectional area of the permalloy runner 304 multiplied by a rate of change of magnetic flux with respect to a change of time.
V=n*A*dB/dT (1)

In calculating voltage V of equation (a), the variable N is equivalent to the number of turns of coil 304, and the variable A represents the cross-sectional area of the permalloy runner 304. The variable B represents flux density, while the variable H represents flux, while the variable H_{c}, represents the flux chirp. The formulation dB/dT represents the rate of change of the magnetic flux linking the interfacing circuit with respect to change in time.

It is important to note that the permalloy material itself can exhibit a “snapping action”, that once the field crosses through 0 Gauss, to a particular level (e.g., H_{c}=flux chirp), the magnetization quickly “snaps” to the opposite direction. This snapping or chirping occurs extremely fast, on the order of nano seconds. Thus, dB is small, and dt is very small, so dB/dT is very large, and thus the voltage (i.e., calculated via equation 1 above) is large.

Because the magnetization can chirp in either direction (dB will be either sign), the voltage can be positive and negative. This feature can provide the direction of the magnetic field change. The resistance of permalloy is an even function (i.e., it does not “know” direction), so a single device based on conventional configurations will not provide both speed and direction information. Normally, two bridges would need to be placed in such a configuration physically offset to provide speed and direction information. The embodiments described herein, however, do not require the placement of two bridges in this manner. Due to the short time duration of the magnetization flip described herein, however, the magnetic sensor described herein is highly sensitive and can operate without electrical current or upon a negligible electrical current.

FIG. 5 illustrates a block diagram of a configuration 500 in which an interfacing circuit 504 is adapted for use with a ferromagnetic runner 502 and a coil structure 506, in accordance with an alternative embodiment of the present invention. Note that ferromagnetic runner 502 can be implemented as a permalloy runner such as, for example, permalloy runner 100 depicted in FIGS. 1-3. Similarly, coil structure 506 can be implemented as a coil structure such as, for example, coil 304 described herein.

Thus, ferromagnetic runner 502 can be located relative to a target (not shown in FIG. 5), and the coil structure 506 wound about the ferromagnetic runner 502, such that when a magnetic field changes direction along an axial length of the ferromagnetic runner 502, a voltage is induced in the coil structure 506 that is proportional to a time range of change of a magnetic flux thereof. The interfacing circuit 502 functions to interface the ferromagnetic runner 502 and the coil structure 506, wherein the ferromagnetic runner 502 and the coil structure 506 are integrated with the interfacing circuit 504 to thereby produce a magnetic sensor for magnetically sensing the target.

Several advantages can be obtained by implementing embodiments of the present invention within the context of a magnetic sensor configuration. For example, embodiments generally rely upon the magnetization reversal phenomenon in a manner that eliminates hysteresis components in associated magnetic sensor integrated circuits, which in turn can also lower the overall current required by such integrated circuits. Note that as utilized herein, the term “hysteresis” refers generally to the lagging of an effect behind its cause. Another advantage of the present invention stems from the fact the magnetic sensor described herein does not require the use of many ferromagnetic cells to measure the direction of magnetization.

The embodiments and examples set forth herein are presented to best explain the present invention and its practical application and to thereby enable those skilled in the art to make and utilize the invention. Those skilled in the art, however, will recognize that the foregoing description and examples have been presented for the purpose of illustration and example only. Other variations and modifications of the present invention will be apparent to those of skill in the art, and it is the intent of the appended claims that such variations and modifications be covered.

The description as set forth is not intended to be exhaustive or to limit the scope of the invention. Many modifications and variations are possible in light of the above teaching without departing from the scope of the following claims. It is contemplated that the use of the present invention can involve components having different characteristics. It is intended that the scope of the present invention be defined by the claims appended hereto, giving full cognizance to equivalents in all respects.

1. A magnetic sensor, comprising:
a ferromagnetic runner located relative to a target; and
a coil structure wound about said ferromagnetic runner, such that when a magnetic field changes direction along an axial length of said ferromagnetic runner, a voltage is induced in said coil structure that is proportional to a time range of change of a magnetic flux thereof.

2. The magnetic sensor of claim 1 wherein said coil structure is wound tightly about said ferromagnetic runner, such that said coil structure possesses a number of turns thereof, which is sufficient to achieve a voltage spike amplitude for said interfacing circuit induced therein when said magnetic field changes direction along said axial length of said ferromagnetic runner.

3. The magnetic sensor of claim 1 further comprising a plurality of interconnecting metals for integrating said ferromagnetic runner and said coil structure with said interfacing circuit.

4. The magnetic sensor of claim 1 further comprising a conductive semiconductor layer located beneath said ferromagnetic runner and an insulated metal to thereby integrate said ferromagnetic runner and said coil structure with said interfacing circuit.

5. The magnetic sensor of claim 1 wherein said ferromagnetic runner comprises a permalloy runner.

6. The magnetic sensor of claim 1 wherein said coil structure comprises a single coil tightly wound about said ferromagnetic runner.

7. The magnetic sensor of claim 1 wherein said ferromagnetic runner comprises a magnetoresistive material.

8. The magnetic sensor of claim further comprising an interfacing circuit for interfacing said ferromagnetic runner and said coil structure, wherein said ferromagnetic runner and said coil structure are integrated with said interfacing circuit to thereby produce a magnetic sensor for magnetically sensing said target, wherein said magnetic sensor is highly sensitive and operates upon a negligible electrical current.

9. The magnetic sensor of claim 1 wherein said voltage induced in said coil structure is equivalent to a number of turns of said coil structure multiplied by a cross sectional area of said ferromagnetic runner multiplied by a rate of change of magnetic flux with respect to a change of time.

10. A permalloy magnetic sensor, comprising:
a permalloy runner located relative to a target;
a single coil wound about said permalloy runner, such that when a magnetic field changes direction along an axial length of said permalloy runner, a voltage is induced in said single coil that is proportional to a time range of change of a magnetic flux thereof;
a plurality of interconnecting metals for integrating said permalloy runner and said coil with said interfacing circuit; and
wherein said single coil is wound tightly about said permalloy runner, such that said single coil possesses a number of turns thereof, which is sufficient to achieve a voltage spike amplitude induced at said interfacing when said magnetic field changes direction along said axial length of said permalloy runner, wherein said magnetic sensor is highly sensitive and operates upon a negligible current.

11. The magnetic sensor of claim 10 further comprising an interfacing circuit for interfacing said permalloy runner and said coil structure, wherein said permalloy runner and said coil structure are integrated with said interfacing circuit to thereby produce a magnetic sensor for magnetically sensing said target, wherein said magnetic sensor is highly sensitive and operates upon a negligible electrical current.

12. The magnetic sensor of claim 10 wherein said voltage induced in said coil structure is equivalent to a number of turns of said coil structure multiplied by a cross sectional area of said permalloy runner multiplied by a rate of change of magnetic flux with respect to a change of time.

13. A magnetic sensor method, comprising the steps of:
winding a coil structure about a ferromagnetic runner, such that when a magnetic field changes direction along an axial length of said ferromagnetic runner, a voltage is induced in said coil structure that is proportional to a time range of change of a magnetic flux thereof; and
interfacing said ferromagnetic runner and said coil structure to thereby produce a magnetic sensor for magnetically sensing said target, wherein said magnetic sensor is highly sensitive and operates upon a negligible electrical current.

14. The method of claim 13 wherein said coil structure is wound tightly about said ferromagnetic runner, such that said coil structure possesses a number of turns thereof, which is sufficient to achieve a voltage spike amplitude for said interfacing circuit induced therein when said magnetic field changes direction along said axial length of said ferromagnetic runner.

15. The method of claim 13 further comprising the step of providing a plurality of interconnecting metals for integrating said ferromagnetic runner and said coil structure with said interfacing circuit.

16. The method of claim 13 further comprising the step of locating a conductive semiconductor layer located said ferromagnetic runner and an insulated metal to thereby integrate said ferromagnetic runner and said coil structure with said interfacing circuit.

17. The method of claim 13 wherein said ferromagnetic runner comprises a permalloy runner.

18. The method of claim 13 wherein said coil structure comprises a single coil tightly wound about said ferromagnetic runner.

19. The method of claim 13 wherein said voltage induced in said coil structure is equivalent to a number of turns of said coil structure multiplied by a cross sectional area of said ferromagnetic runner multiplied by a rate of change of magnetic flux with respect to a change of time.

20. The method of claim 13 wherein the step of interfacing said ferromagnetic runner and said coil structure to thereby produce a magnetic sensor for magnetically sensing said target, wherein said magnetic sensor is highly sensitive and operates upon a negligible electrical current, further comprises the step of interfacing said ferromagnetic runner and said coil structure utilizing an interfacing circuit.
